(19) United States
(12) Patent Application Publication
(10) Pub. No.: US 2009/0126795 A1
(43) Pub. Date: May 21, 2009

(54) 3-D energy cell w/t reflector

(76) Inventor: Charles J. Williams, Hartsville, SC (US)

Correspondence Address: CHARLES J. WILLIAMS, 2512 HIGHLINE ST., HARTSVILLE, SC, 29550, US

(21) Appl. No.: 12/288,416

(22) Filed: Jan. 10, 2009

(51) Int. Cl. H01L 31/02

(52) U.S. Cl. 136/259

(57) ABSTRACT

I propose a 3-D (three dimensional) alternative energy panel I call the “Earth Energy Cell”. It will be able to use several means of earth energy.
Solar
Wind
Thermal
Induction
   It will be able to collect light from 360 Degrees. Not from only one south facing direction.

The inventor is at present disabled due to colon cancer and was harmed by the results. Since Charles are unable to sit or stand more than a few minutes at a time, all of this design and research work was done from his bed. However, his mind is working quite well as though in an accelerated rate. He (Charles) has been working on this solar design for several years from his bed. Charles has been interested in alternative energy since he was a child. He has a degree in drafting & design, worked over 20 years as an engineer with a large company. Charles has also traveled to many countries in his trouble-shooting and problem solving capacities including Lebanon, Iran, China and many others. He has received a citation from the State Department for some work in Iran. This was from a company years earlier that I will not mention at this point.

His job function at his latest employer was not in the field of solar energy but he did receive extensive training and experience in furnaces and the art of heat transfer. He has a great knowledge in programmable computers, PLC,s and manufacturing process and design. His last assignment was a plant startup in China, but was very sick when he arrived home. After spending several days in the hospital it was discovered he has stage IV color cancer and has extensive surgery to remove (2) large tumors. He also lost a large portion of his intestates. He then went through the regular cancer treatment of radiation, chemo and other treatments. At one time he was only given less than 4 months. As results of the radiation, his back or spines was greatly damaged and had (2) more operation to remove bad portion of the 2 lower spines and have to suffer with pain that can only be made bearable with the use of very strong medication. Charles now believes that this was the only way he could have designed a solar concept which required that much research and design. Normally, his trouble-shooting and problem solving abilities would have gone to benefit the company. This sickness was then a good thing and he had lot more to worry about that a cancer. It was however not an easy task and required a long time working only when he could only think about a problem. His view on life is remarkable. Most of his design concept of alternative energy came as a result of going without any form of heat or cooling for over two years. The heat pump was broken, no money to repair or replace it and trying any means to keep him and wife with some heat. Again, he gathered a lot of data than lead to a reduction of electrical power reduction from $420 per month to less than $100 per month. Charles then put the information on a website for anyone to use. That is why he insisted on an alternative energy source that can be affordable because we could not afford to buy a system. At that time a system cost was $8.79/watt or around $16,000 for a system. Today it is no better.

### BACKGROUND OF THE INVENTION

The solar panels started out as a flat panel with only one direction for sun light to be exposed to the PV cells. At present we still only use this design. I did see a solar collector that gathered rays by means of the Fresnel lens (U.S. Pat. No. 5,151,826) but this concept is not suited for the purpose of this energy unit. The reason being: heat, refraction rate, and more. I will now list the design concept of an earth energy cell which I call it. (See FIG. 21, 24, 30)

Allow for 360° coverage for light rays exposure or a much as possible. This is the main purpose for the 3-D design of the energy unit. If we use the most efficiency shape for obtaining the most surface area to allow for the maximum amount of PV cells, we would use a sphere. This shape also allows us to place one sphere inside another for other uses. Since there are 314% more surface area in a sphere that a flat panel we can place a lot more PV cells in the same or less foot print area. (See FIG. 22)

Use as many energy types as possible combined in one unit. (See FIG. 10)

Protect the PV cells from excess heat and objects that could harm the sensitive parts of the solar unit. (See FIG. 24)

Design a solar panel that will allow for designers of PV cells more design options like size, shape, etc. This will add us in another reason for this design. (See FIG. 21. 30)

Cost of alternative energy unit. If the cost cannot be reduced to allow for everyone to install a solar unit, it will not impact the energy usage today or tomorrow. (See line 78,79,112,113,114,115)

Reduce the electrical cost of the consumers by reducing their power bills from grid power.

Impact as many manufacturing jobs in the U.S. as we can. We must introduce more jobs if we are to enjoy the many benefits we or so blessed to receive. If we make room for jobs in our country and not send them oversees, the circle of wealth and growth will not be broken. When we buy goods that were imported, the profit may stay in the U.S. but the circle is broken. The man or women that made the units did not buy the unit. The labor cost went overseas.

### BRIEF SUMMARY OF THE INVENTION

Use clear spheres to collect light rays from the sun. We will call this outer sphere as the main sphere. (See FIG. 1, 10) We need only at this time be concerned for our climate but also at a later time and allow for engineers to design it for near and outer space. But at the present time let's make it work but as cost efficiency as we can. I propose to make the first one from clear NO. 1 and No. 2 recycled plastic. This is of course is drink bottles, etc. I will explain more about this in the recommended manufacturing process later down or at a later time. (See FIG. 14)

Use a second sphere or cause the protons, electrons, Ions to multiple to at least 2 or more times. We can do this like the binoculars allow us to see at a greater distance. I believe that multiplying of Ions can also be aided by the addition of a strong magnetic field around and inside the unit. (See FIG. 21)

Add a third sphere to house the PV cells. This sphere should also absorb heat from the unit and protect the PV cells from overheat. We must then transfer this heat to a heat transfer sphere. (See FIG. 30 (a) and FIG. 31)

The heat transfer spheres will serve several purposes. It will be the source of the magnetic field, absorb heat from other parts, and have the means to store and transfer heat to outside storage units and radiators for passive heat. (See FIG. 31 and FIG. 30)

Design a concave reflector to transfer light rays to all sides of the solar unit. Not to concentrate the rays but to reflect them at as many points of the unit as we can. That is why we will a different concept that the collectors on the markets. Remember we do not want to build heat at this point. We just want the light rays. We will get the heat anyway. But do not want to transfer the energy into heat. (See FIG. 22)

Note: We may use this design for just solar or passive energy if needed for cost. But we can use more than one type of energy in one central unit. We do want to increase the total output to at least 500 watts of electrical power. (See FIG. 10)

Allow the unit(s) to be mounted on a pole and not require a large, south facing roof. We can if needed mount on a roof and aid in exhausting the heat from the attic of a home for greater energy efficiency. (See FIG. 16 and FIG. 24)

This design will also allow us to have room and means to add objects and materials to enhance the light spectrum and frequencies to the PV cells.(See FIG. 32) If we can separate and direct the light spectrums with the most electrical energy to the PV cells we will greatly increase the overall efficiency of the solar unit. This could be none with directing the light rays to the PV cells as in FIG. 32, or by using a gas filled tubes like argon, etc. to allow only the spectrum we wish to only pass through. This would not be possible with the present flat panel design. Other companies could also invent plastic material specially designed to allow only with light rays we need for the most electrical energy to pass while reflecting the harmful one like radiation resulting in excessive heat to the PV cell.

This 3-D design solar or energy cell is a new design point for alternative energy many others can and will take advantage of this and add our country to be energy dependant from energy's that harm our plantlet.

I also wish for other companies to have access to this design to use and improve on. This patent in NOT for sell to the highest bidder! It could be too important for one company. If not needed or wanted I have hurt no one. An example of this is Japan. Their average apartment is less that 500 square foot. Not enough flat, sun oriented root tops for much flat panel solar collectors. But with this 3-D design the people could get enough voltage from even one unit to provide both electrical and thermal energy. So could we. This design has taken me several years, much funds, and I have had zero funding from outside sources. I therefore owe no one. No investors to compensate.

### BRIEF DESCRIPTION OF SEVERAL VIEWS OF THE DRAWING

FIG. 10: This shows how the energy unit may be installed for wind power. Showing how we will drive the unit with wind, using half cups. This picture also shows the fluid flow to the unit to obtain thermal energy. This will also show how we will get the energy to obtain the Induction Energy.

FIG. 14: A drawing to show the overall shape of the Earth Energy Cell. It also shows how we can incase several spheres inside each other for a combo unit. Since this is now possible, the cost of a solar array will be lower. Since no metal parts are needed. The structural integrity of a sphere is among the strongest of designs. These spheres maybe fabricated from recycled plastics like No. 1, No. 2, etc. Look for the recycle symbol on the bottom of most plastic containers like drink bottles. Most clear plastics may be used to reduce carbon foot-print. This is an added benefit with this design.

FIG. 15: A picture of a honeycomb to show the shape we can use to direct the light rays to the PV spears. Nature uses this shape.

FIG. 16: A drawing showing a roof mounted unit used to also exhaust attic heat. A good benefit for energy efficacy and good circulation in the attic helps remove moisture.

FIG. 17: A small drawing of a sphere which will be the shape of the earth energy cell.

FIG. 18: Picture of a standard flat solar panel. This type must be oriented to toward the sun as precisely as possible. Different areas of the country must be oriented differently and changed seasonally. This type also requires a large flat area to perform correctly.

FIG. 19: Drawings showing a simple magnetic field. This shows the poles as traveling from north to south but may be configured to any directions as needed for best results.

FIG. 21: A drawing showing some parts assemble of the energy unit. Also how the light rays enter the unit to hit the solar cells. Note that if we drill a flat sheet with holes or any shaped, then heat the flat material when we form the flat sheet in a sphere shaped object that all the holes will point to the center of the sphere.

FIG. 22: Drawing to show simple light path of sun rays to sphere shaped energy cell. Notice that we can now expose as much as 360° to sun light. This also demonstrates that the energy cell does not have to be oriented. Like south, north, etc. This gives us the flexibility to mount all most anywhere sun light is available.

FIG. 23: A drawing of the parts of the Induction fields to obtain induction energy. This drawing shows the magnetic fields and the wire core to make up the induction generator.

FIG. 24: 3-D view of the Earth Energy Cell.

FIG. 25: Drawing showing that a flat panel when formed into a sphere will direct all rays to the center point of the sphere.

FIG. 30: Assemble of Spheres Drawing

FIG. 30 (a) Magnetic Core

FIG. 30 (b) Outer Main Sphere

FIG. 30 (c) Honeycombed drilled light amplification sphere

FIG. 30 (d) Pv sphere and Pv cells

FIG. 30 (e) Wire coils for Induction Energy

FIG. 30 (f) Magnetic Fields

FIG. 30(b [av]) Drawing of another Design of the outer sphere.

FIG. 31: A drawing showing the possible flow of fluid to and from the thermal collector part, for passive energy.

FIG. 32 Drawing showing the light ray's path from the outside sphere then bounced and redirected toward the centerline which will cause the rays to hit the PV cells at a perpendicular position. Also used to cause the rays to hit the walls and increase protons. This could also be a gas filled tube to allow only the light spectrum we wish to pass. We may also increase the number on Ions to the PV cells. (See FIG. 32 for greater details

### DETAILED DESCRIPTION OF THE INVENTION

### Solar Energy

Collect as many types on light rays into the sphere and prevent as mush anti-reflection as possible. Also to change the index of refraction that will lead to growth of energy producing protons to maximize the total electrical output. Unlike the Fresnel lens that would focus the rays, we wish to shatter the rays, collect them back, cause them to collide and multiple, then point them to hit the PV cells after passing through a magnetic field. (See the Limit)

This is a simple drawing showing a wire sphere with a strong magnetic field in and around it. This is the 3-D shape I propose. Physics tells us that when light passes through a magnetic field the light waves will bend. If we gather this rays at that moment let them pass through an object similar to an optical fiber cable, the rays will hit the reflective walls surrounding the fibers and split into 2, 4, 6, etc. It our case we will not use an optical fiber cable, instead it will be hollow to avoid refractor lose. The light rays entering from the outer sphere will hit the deflective material. Then, bouncing from side to side and will leave the other end and be directed to the PV cells.

Our light gathering material will be a simple hexagon shaped hollow plastic straw like material with reflective coating on the inside or other filter type material.

This reflective straw will be mounted on the second sphere. I will furnish a drawing to reflect this concept. (Also see Impurity photovoltaic)

### Wind Energy

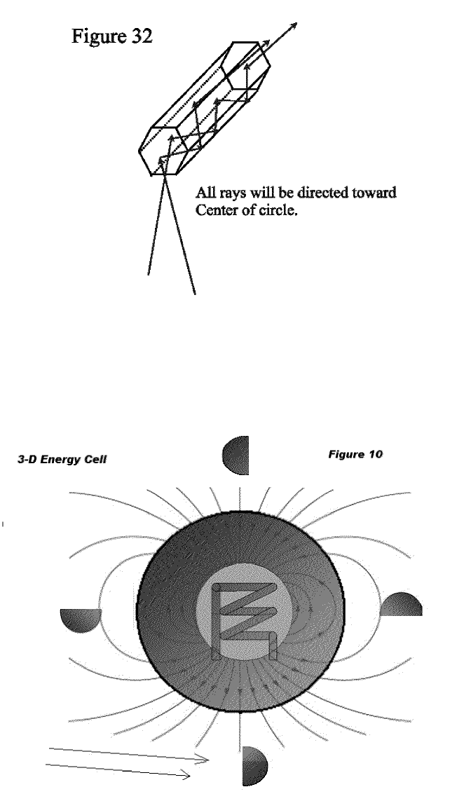

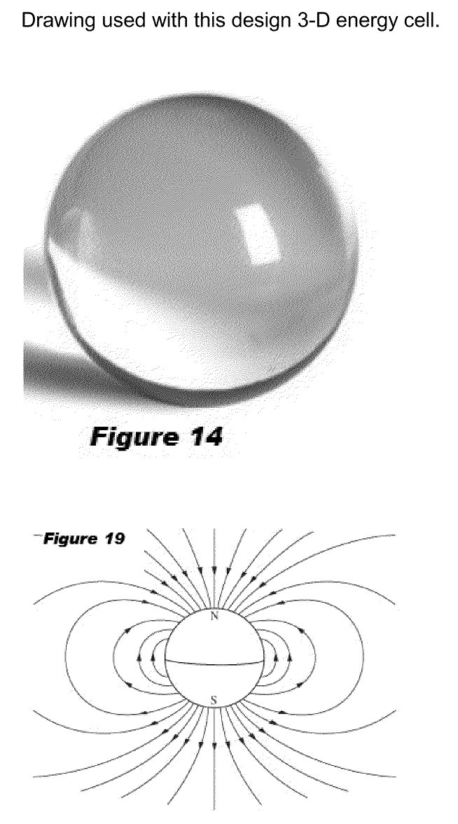

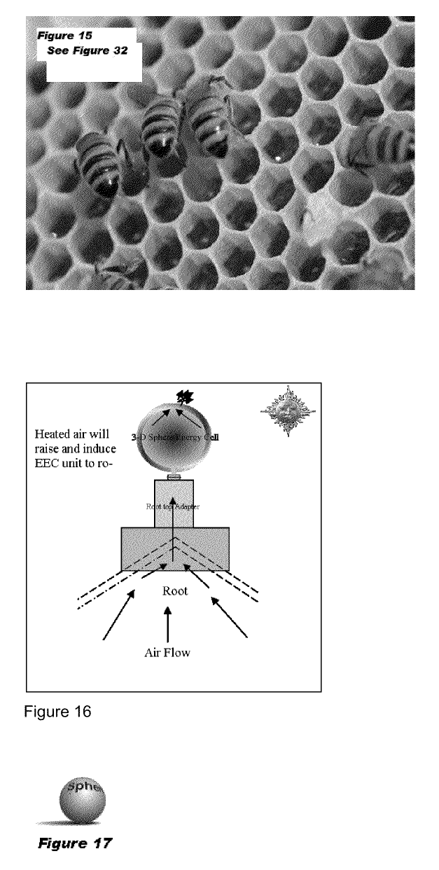

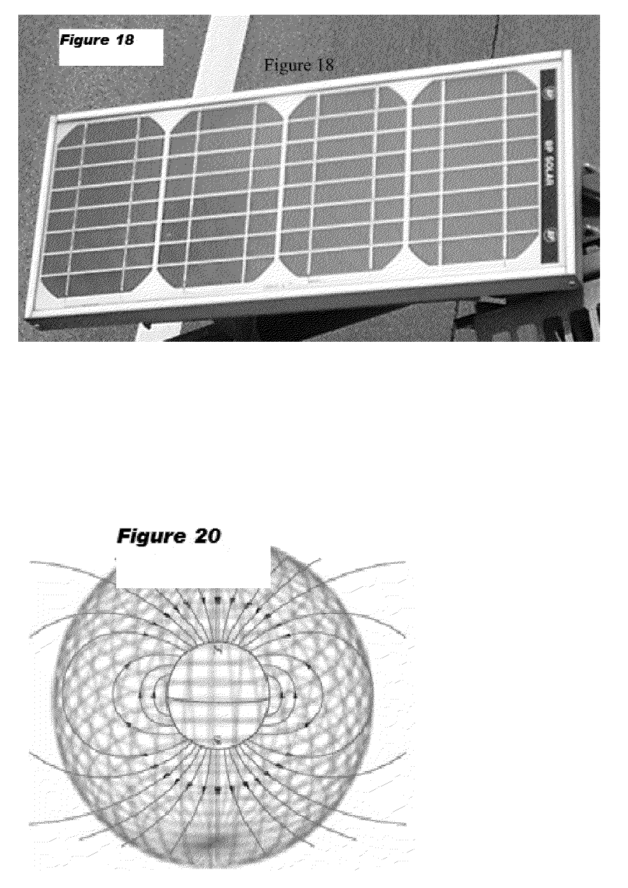

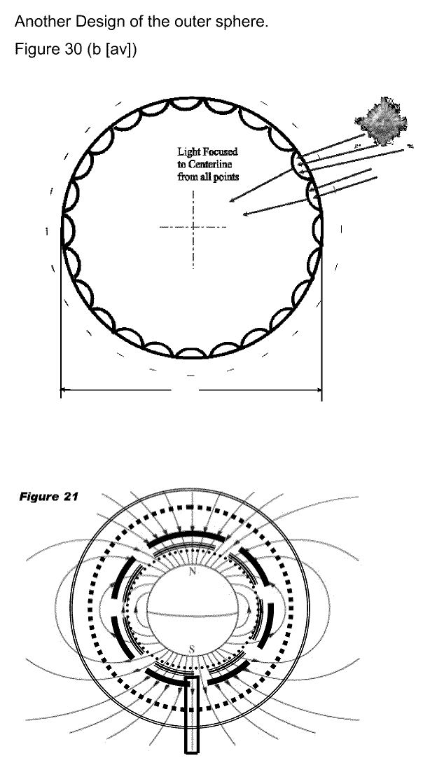

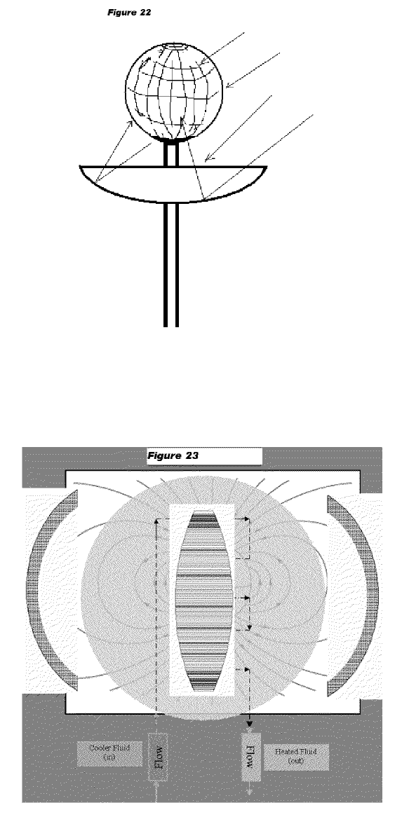

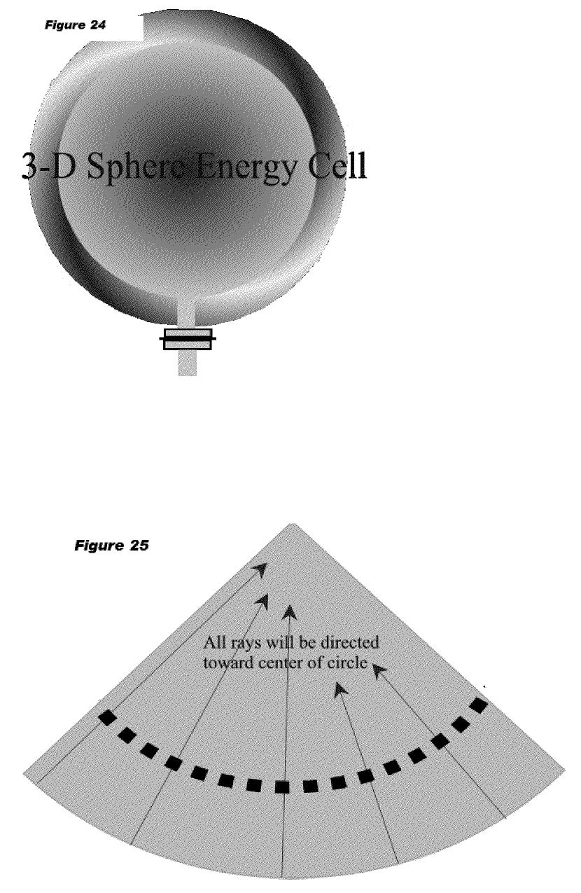

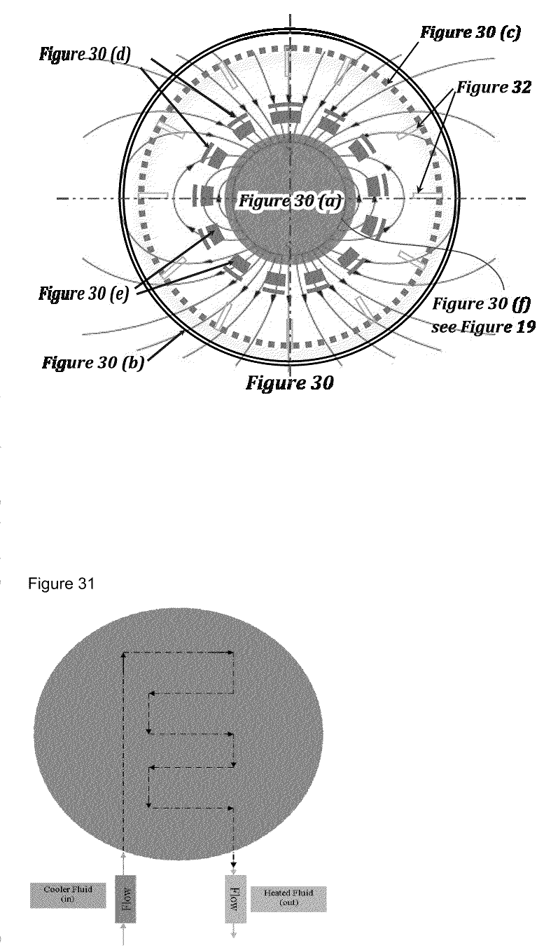

The spheres will be wind driven by means of (4) or more cup shaped objects extending from the unit. All spheres will be driven except the innermost magnetic sphere since fluid lines will be attached to this for Heat Transfer. We have designed a method to prevent excess speed by altering the pitch of the cups. The units will only drive in one direction. I will provide drawing. (See FIG. 10)

### Induction Energy

Induction energy is obtained from the wind driving the spheres. Remember that the innermost sphere is a large magnet. Let's look at the Law of Magnetism.

### Law of Magnetism

Alternators generate electricity by the same principle as DC generators, namely, when the magnetic field around a conductor changes, a current is induced in the conductor. Typically, a rotating magnet called the rotor turns within a stationary set of conductors wound in coils on an iron core, called the stator. The field cuts across the conductors, generating an electrical current, as the mechanical input causes the rotor to turn. Credit http://en.wikipedia.org/wiki/Main_Page

Since we already have a magnetic field, when we rotate the winding (or the Stator) around the field current will flow through the winding. The output will be promotional to the speed. We will not have very fast speed but never less we will get some voltage to help us. I have calculated the maximum speed (rpm) will be only 126 rpm. I will work on this but it is better than none. Besides, we need the magnetic field to help with the protons regeneration. If we rotate the wire core in a magnetic field, electrical energy will flow within the wire core. This will produce induction energy.

### Thermal

The Core will/maybe made of all magnetic like Rare Earth Magnets, except man-make for cost. The (8) or more copper wire coils will be mounted (See FIG. 23) to inside of the PV sphere or on a sphere itself. This Sphere will not rotate but when the next sphere (PV Sphere) rotates around wire coil energy will flow though the wire coils.

### Thermal Energy

We have a goal in this project to try to keep the temperature of the PV cells at the proper design specifications of the cells from maximum efficiency. I have not seen any solar panel on the market that even concerns about this. I also saw that the operating temperature range of best PV efficiency is a narrow one.

We can use the heat generated from the sun rays for a good purpose. I am hoping we can get a PV cell manufacturer to provide us with specifications far best performance, with the operating temperature being as high as possible for good heat transfer. If we keep in mind of one law of heat transfer, that in order to have a storage temperature of 90-100° that we need a temperature of around 100-110°. Remember that heat will only transfer from the hottest to the coolest temperature. I hope this will not be a problem with the PV cells and if it is too high, I will use what I can get. I do have a good knowledge of heat transfer and have several ideas. (See FIG. 31)

One of these is the use of wax to store our heat made to melt at a designed temperature. This is part of our research paper.

Paraffin wax (C25H52) is an excellent material to store heat, having a specific heat capacity of 2.14-2.9 J g-1 K-1 (joule per gram per Kelvin) and a heat of fusion of 200-220 J g-1.[6] This property is exploited in modified drywall for home building material: it is infused in the drywall during manufacture so that, when installed, it melts during the day, absorbing heat, and solidifies again at night, releasing the heat. Paraffin wax phase change cooling coupled with retractable radiators was used to cool the electronics of the Lunar Rover.

Wax expands considerably when it melts and this allows its use in thermostats for industrial, domestic and, particularly, automobile purposes.

We have designed a special valve to allow flow when needed and to prevent flow when not.

### REFERENCE NOTES

Electric charge: A property of some subatomic particles, which determines their electromagnetic interactions. Electrically charged matter is influenced by, and produces, electromagnetic fields.

Electric current—a movement or flow of electrically charged particles, typically measured in amperes.

Electric field—an influence produced by an electric charge on other charges in its vicinity.

Electric potential—the capacity of an electric field to do work, typically measured in volts.

Electromagnetism—a fundamental interaction between the magnetic field and the presence and motion of an electric charge.

Electrical phenomena have been studied since antiquity, though advances in the science were not made until the seventeenth and eighteenth centuries. Practical applications for electricity however remained few, and it would not be until the late nineteenth century that engineers were able to put it to industrial and residential use. The rapid expansion in electrical technology at this time transformed industry and society. Electricity's extraordinary versatility as a source of energy means it can be put to an almost limitless set of applications which include transport, heating, lighting, communications, and computation. The backbone of modern industrial society is, and for the foreseeable future can be expected to remain, the use of electrical power.

### Impurity Photovoltaic's (for Research Data)

There has been some work on the use of deliberate impurities to produce mid-energy states within single crystal structures. These cells would combine some of the advantages of the multi-junction cell with the simplicity of existing silicon designs. A detailed limit calculation for these cells with a wide variety of impurities suggests a maximum efficiency of 77.2%. To date, no commercial cell using this technique has been produced.

This is one of the goals we are striving for in this design. The other is: Shockley-Queisser limit as shown on next page:

That is why we have chosen the “Straws” to be shaped as they are and be hollow or the filter material. The air will increase the holes to increase these limit calculations for efficiency. The answer to our solar problem is more efficiency in the cells and design of the panels. Not the amount of them. If enough sun light in 1 ft² is more than enough to serve an entire town, then the answer is “We must learn how to use it”.

### The Limit (for Research Data)

The key factor that leads to the calculation of the Shockley-Queisser limit is the amount of electrical energy that is produced per photon.

Since the act of moving into the conduction band requires energy, only photons with more than that amount of energy will create power, and the power produced will be any leftover energy after boosting the electron to the conduction band. In silicon the conduction band is about 1.1 eV away from the valence band, which corresponds to red light. In other words, photons of red, yellow and blue light will all contribute to power production, whereas infrared, microwaves and radio waves will not.[4] This places an immediate limit on the amount of energy that can be extracted from the sun. Of the 1,000 W/m², about half of that has less than 1.1 eV of energy, and will not produce power in a silicon cell. That means there is a theoretical conversion efficacy of about 50% or less, ignoring all other factors.

Another important contributor to losses is that any energy above and beyond the band gap is lost; while blue light has roughly twice the energy of red light, there is no practical way to capture that energy. The electron is ejected with higher energy, but it loses this as it travels toward the p-n junction, this energy being turned into heat in the crystal. The Shockley-Queisser limit calculation is based on this analysis, considering the difference in energy between the absorbed and emitted photons at 6000° K for the sun and 300° K for the cell.

This is the essence of the Shockley-Queisser limit calculation, which states that a single-junction cell made of silicon will have a theoretical peak performance of about 30%, or about 300 W/m².

Shockley and Queisser work considered the most basic physics only. There are a number of other factors that further reduce the extracted power. Many of these have been explored since the 1980s. Lands-berg and Baruch added various practical considerations like re-emission, while a number of researchers have attempted to characterize other losses in the cell, like interstitial defects. This latter effect explains why polysilicon cells are always outperformed by their single-crystal cousins. Every photoelectron leaves behind a “photohole”, an ionized atom that will attempt to catch any passing electron. If a cell were placed in conditions where a single photoelectron/hole was produced, that electron has almost no chance of re-combining with the hole it left behind; the force towards the p-n junction overwhelms it. As the rate of photo-production increases, the number of holes already in the bulk crystal grows. These are the holes left behind by previous excitations that have not yet been filled by electrons being returned to the cell. Eventually the number of holes will grow so great that every new photoelectron will meet a hole before reaching the junction, placing a limit on the rate of production.

### Exceeding the Limit

It is important to note that the limit makes several fundamental assumptions; that the cell contains a single p-n junction, that the junction is tuned to visible light, and that any extra energy in the photons is lost. None of these assumptions is necessarily true, and a number of different attacks have been made to significantly surpass the basic limit.

We are trying to exceed the limit. We must if we are to succeed in utilizing the sun as a primary source of power.

### SUMMARY

If I am correct with this design solar unit I call the “Earth Energy Cell”, it will require a lot of input from many sources and companies and experts from many fields. I think it much be handled by a company that can get it done the best ways with the best personnel, without any restrictions. This department can only be the U.S. Department of Energy. This energy cell should be available to all citizens, even the ones that cannot afford to pay, still needs help. If successful this concept could reduce or eliminate part/all cost of electrical energy. Would it not be nice to know that at some time in a person's life, the cost of energy is also provides so the cost of existence would be far lesser. We would love to see some form of program to set aside a little fund from sells to help the people that cannot to pay, get help at no or little cost. A solar system is not for status purposes but to help all in alternative energy and out Planet.

### Patent Research Data

I did NOT find any sphere shaped solar panels nor any 3-D shaped solar panels to show as reference or improvements. I did find two patents of interest. One was about a sphere shaped patent used at the space station. I will paste the data of this for you to check.

I also wanted to show why the protons and ions multiplying theory I am looking for will work on other devices that may/may not use the same as I am proposing. However, the best example is much classified so I will not even state. I am sure I do not need to use it.

### Spacecraft Solar Panel Spherical Trickle Charger

U.S. Pat. No. 6,511,022

Filing date: Jun. 24, 2002

Issue date: Jan. 28, 2003

Inventor: Ernie Y Robinson

Assignee: The Aerospace Corporation

Primary Examiner: J. Woodrow Eldred

Attorney: Derrick Michael Reid

application Ser. No. 10/179,787

Also see another patent that might help in research that I found of interest but of a flat panel with a part that was unique to a flat panel and did use in increase in area for a good purpose. Our sphere shape does use this increase in area to help spread the light but in a much different way. I did like that design.

U.S. Pat. No. 5,167,724

Filing date: May 16, 1991

Issue date: Dec. 1, 1992

Inventor: Clement J. Chiang

Assignee: The United States of America as represented by the United States Department of Energy Also see sub-class 359 Optics: Systems and Elements, for optical devices of general utility.

U.S. Classification 244/173; 136/293; 323/906

International Classification B64G 144

1. Increase the total amount of PV cells by using a 3-Dimensional shape to house cells rather than a flat panel. This will allow for 360 degrees coverage for sunlight to enter the unit. This should yield us 314% more area for PV cells.

2. If we use a shear to house the solar cells as in claim 1, we can amplify the ions in the sun light, by passing the rays though a filter. If the ions gets bounced around in the inside surface they will multi-ply. This bouncing may be accomplished by several ways but we propose a honeycomb shaped filter on the inside of the outer shear. At least we have an option as of how we introduce the light rays to the solar cells.
We know that sunlight is in the form of electromagnetic radiation from the infrared (long) to the ultraviolet (short) wavelengths. We claim to be able to use both forms with our Energy Cell. Also, we can use any solar cell of the market or cells newly designed in the future. This means we can start to manufacture our Energy Cell now, not later at some point in time.

3. Gain Energy from allowing the sun rays pass though an Electromagnet or Earth based magnetic field using rare earth magnets or manufactured magnetic build to be a sphere shaped. By this means we can change the polarity of the field to attract more energy rays to the solar cells.

4. (Note: This was omitted from original claims but was included in the title. (w/t reflector) Use a Reflector to focus the light rays to all sides of the Solar Panel.
The reflector will be a shinny, parabolic, round shaped disk, beneath and under the spheres'.
It will be mounted in the same fashion as the unit.
The radius will be diameter of Energy Cell+12.0″ min.
This will be angled at app. 22½° facing south if possible, but not required.
claims benefits
Using claim 1, 2, and 3, we can combine more types of Earth energy into the same solar unit. That is way we call this an Energy Cell rather that solar panel. Let's also use the power of the wind, and passive energy. We already know that we will get heat from the sunlight. With claim 2 and claim 3 we may also get heat from deflection of the rays.
claim 1 will allow us to protect the solar cells, extending their life spam. If a solar panel lasts ten years and we recover our cost in about 10 years, we have to keep replacing. I do not like to talk about alternative energy payback! But some people do. Saving our planet and gaining Energy dependency is more important. By using as much Earth Energy into one unit we can help with this.
